(19) United States
(12) Patent Application Publication
(10) Pub. No.: US 2004/0227236 A1
(43) Pub. Date: Nov. 18, 2004

(54) Semiconductor device, electronic device, electronic apparatus, and methods for manufacturing carrier substrate, semiconductor device, and electronic device

(76) Inventor: Toshihiro Sawamoto, Matsumoto-shi (JP)

Correspondence Address: HARNESS, DICKEY & PIERCE, P.L.C., P.O. BOX 828, BLOOMFIELD HILLS, MI, 48303, US

(21) Appl. No.: 10/801,089

(22) Filed: Mar. 15, 2004

(30) Foreign Application Priority Data
Mar. 17, 2003 (JP) 2003-072563

(51) Int. Cl. H01L 23/10

(52) U.S. Cl. 257/734

(57) ABSTRACT

A technique is provided to reduce variations in height of packages even when any one of the packages is warped. According to the technique, the thicknesses of lands disposed on a carrier substrate gradually increase from the inner region to the outer region of the carrier substrate. The thicknesses of lands disposed on opposite carrier substrates gradually increase from the inner region to the outer region.

### RELATED APPLICATIONS

This application claims priority to Japanese Patent Application No. 2003-072563 filed Mar. 17, 2003 which is hereby expressly incorporated by reference herein in its entirety.

### BACKGROUND OF THE INVENTION

1. Technical Field of the Invention

The present invention relates to a semiconductor device, an electronic device, an electronic apparatus, and methods for manufacturing a carrier substrate, a semiconductor device, and an electronic device. In particular, the present invention is suitable for application to a composite structure, such as a semiconductor package.

2. Description of the Related Art

In conventional semiconductor devices, stacking carrier substrates mounted with semiconductor chips by solder balls is employed to three-dimensionally mount semiconductor chips.

In mounting semiconductor chips on or above carrier substrates, however, the carrier substrates suffer some warping and semiconductor packages have variations in height because of the difference in the coefficient of linear expansion between the semiconductor chips and the carrier substrates. As a result, the permissible warping in the carrier substrates for the melting temperature of solder is small and thus strict control of the temperature during solder-melting is required.

An object of the present invention is to provide a semiconductor device, an electronic device, an electronic apparatus, and methods for manufacturing a carrier substrate, a semiconductor device, and an electronic device that are capable of reducing variations in height of semiconductor packages even when any one of the semiconductor packages is warped.

### SUMMARY

To solve the above mentioned problem, a semiconductor device according to an aspect of the present invention has a carrier substrate having a plurality of lands that have different thicknesses from each other; and a semiconductor chip mounted on or above the carrier substrate.

Therefore, in this semiconductor device, variations in height of the carrier substrates are accommodated by the thicknesses of the lands. Thus, the semiconductor packages have uniform height even when the carrier substrate is warped.

According to the semiconductor device of an aspect of the present invention, the thickness of each of the lands may gradually vary from the inner region to the outer region of the carrier substrate.

Therefore, in this semiconductor device, the semiconductor packages mounted on or above the carrier substrate have uniform height without complicating the mounting steps, even when the carrier substrate is warped.

According to an aspect of the present invention, a semiconductor device has a first semiconductor package having a plurality of first lands that have different thicknesses from each other; and second semiconductor packages, each having a plurality of second lands that have different thicknesses from each other, the second lands being arranged opposite the first lands.

Therefore, in this semiconductor device, variations in the spaces between the first semiconductor package and the second semiconductor packages are accommodated by both the first lands and the second lands. Thus, the second semiconductor packages are mounted on the first semiconductor package without increasing variations in height of the second semiconductor packages, even when the first semiconductor package or the second semiconductor packages are warped.

According to the semiconductor device of an aspect of the present invention, the thickness of each of the first lands and the second lands may gradually increase as a space between the first semiconductor package and the second semiconductor packages increases.

Therefore, in this semiconductor device, the space between the first lands and the second lands is uniform even when the spaces between the first semiconductor package and the second semiconductor packages are not uniform. Thus, the second semiconductor packages mounted on the first semiconductor package have uniform height.

According to an aspect of the present invention, the semiconductor device may further include bumps bonded to the lands.

Therefore, in this semiconductor device, carrier substrates mounted with semiconductor chips are stacked. Thus, the semiconductor chips are three-dimensionally mounted, resulting in a reduced footprint.

According to the semiconductor device of an aspect of the present invention, the bumps may have substantially the same volume.

Therefore, in this semiconductor device, variations in the spaces between the first semiconductor package and the second semiconductor packages are accommodated without changing the sizes of the bumps, even when one or both of the first semiconductor package and the second semiconductor packages are warped. Thus, the second semiconductor packages mounted on the first semiconductor package have uniform height without decreasing the mounting efficiency.

According to an aspect of the present invention, the semiconductor device may further include insulating films formed on the lands; and openings that are formed in the insulating films and have different opening areas corresponding to the thicknesses of the lands.

Therefore, in this semiconductor device, an etching rate for etching of the surfaces of the lands varies in accordance with the opening areas of the insulating films formed on the lands. Thus, the thicknesses of the lands can vary without repeatedly forming the lands in accordance with differences in the thickness of the lands. As a result, the second semiconductor packages mounted on the first semiconductor package have uniform height without complicating the manufacturing process.

According to the semiconductor device of an aspect of the present invention, the opening areas of the openings may decrease as the thicknesses of the lands increase.

Therefore, an etching rate for etching of the surface of the lands decreases by reducing the opening areas of the insulating films. Thus, the thicknesses of the lands are readily accommodated without repeatedly forming the lands in accordance with difference in thickness of the lands.

According to the semiconductor device of an aspect of the present invention, the first semiconductor package may include: a first carrier substrate having the first lands; and a first semiconductor chip that are flip-chip mounted on or above the first carrier substrate, and the second semiconductor packages may include: second carrier substrates having the second lands; second semiconductor chips mounted on or above the second carrier substrates; bumps for bonding the first lands and the second lands to hold an end of each of the second carrier substrates right above the first semiconductor chip; and seals for sealing the second semiconductor chips.

Therefore, in this semiconductor device, the second semiconductor packages are arranged on the first semiconductor package without increasing height, even when the type of the first semiconductor package is different from that of each of the second semiconductor packages. Additionally, variations in the spaces between the first semiconductor package and the second semiconductor packages are accommodated even when one or both of the first semiconductor package and the second semiconductor packages are warped. Thus, space savings and uniformed height of the second semiconductor packages mounted on the first semiconductor package are accomplished.

According to the semiconductor device of an aspect of the present invention, the first semiconductor package may be a ball grid array package in which the first semiconductor chip is flip-chip mounted on or above the first carrier substrate, and each of the second semiconductor packages may be a ball grid array package or a chip-size package in which each of the second semiconductor chips mounted on or above each of the second carrier substrates is sealed by molding.

Therefore, in this semiconductor device, different types of packages are stacked without necking the bumps, even when the packages are general purpose packages, resulting in more reliable connections between different types of the packages without reducing manufacturing efficiency.

According to an aspect of the present invention, an electronic device has a first carrier substrate having a plurality of first lands that have different thicknesses from each other; a first electronic component that is flip-chip mounted on or above the first carrier substrate; second carrier substrates, each having a plurality of second lands that have different thicknesses from each other, the second lands being arranged opposite the first lands; second electronic components mounted on or above the second carrier substrates; and seals for sealing the second electronic components.

Therefore, in this electronic device, the second carrier substrates are arranged on or above the first carrier substrate and also variations in the spaces between the first semiconductor package and second semiconductor packages are accommodated by both the first lands and the second lands. Thus, the second carrier substrates are mounted on or above the first carrier substrate without increasing the amount of change in thickness of the lands, even when variations in the spaces between the first carrier substrate and the second carrier substrates are large.

According to an aspect of the present invention, an electronic apparatus has a first semiconductor package having a plurality of first lands that have different thicknesses from each other; second semiconductor packages, each having a plurality of second lands that have different thicknesses from each other, the second lands being arranged opposite the first lands; and a motherboard having the second semiconductor packages.

Therefore, in this electronic apparatus, variations in the spaces between the first semiconductor package and the second semiconductor packages are accommodated by varying the thicknesses of the lands. Thus, the second semiconductor packages mounted on the first semiconductor package have uniform height even when the first semiconductor package or the second semiconductor packages are warped.

According to an aspect of the present invention, a method for manufacturing a carrier substrate has the steps of: forming a plurality of lands on a first carrier substrate; forming an insulating film on the plurality of lands formed on the first carrier substrate; forming openings in the insulating film, wherein the openings have different opening areas and expose the surfaces of the lands; and varying the thicknesses of the lands by etching the surfaces of the lands through the openings.

Therefore, in this method, an etching rate for etching of the surfaces of the lands can vary in accordance with the opening areas of the insulating films formed on the lands. Thus, the lands having different thicknesses are formed in a single step without repeatedly forming the lands in accordance with differences in the thickness of the lands. As a result, the thicknesses of the lands can vary without complicating the manufacturing process.

According to an aspect of the present invention, a method for manufacturing a semiconductor device has the steps of: forming a plurality of first lands that have different thicknesses from each other on a first carrier substrate; mounting a first semiconductor chip on or above the first carrier substrate; forming a plurality of second lands that have different thicknesses from each other on second carrier substrates; mounting second semiconductor chips on or above the second carrier substrates; forming bumps on the second lands; and arranging the second carrier substrates on or above the first carrier substrate by bonding the bumps formed on the second lands to the first lands.

Therefore, in this method, variations in the spaces between the first carrier substrate and the second carrier substrates are accommodated by both the first lands and the second lands. Thus, variations in height of the carrier substrates are controlled without adjusting the sizes of bumps or the amount of supplementary solder, even when the first carrier substrate or the second carrier substrates are warped. As a result, the second carrier substrates mounted on or above the first carrier substrate have uniform height without complicating the steps of mounting.

According to an aspect of the present invention, a method for manufacturing a semiconductor device has the steps of: forming a plurality of first lands on a first carrier substrate; forming a first insulating film on the plurality of first lands formed on the first carrier substrate; forming first openings in the first insulating film, wherein the first openings have different opening areas and expose the surfaces of the first lands; varying the thicknesses of the first lands by etching the surfaces of the first lands through the first openings; mounting a first semiconductor chip on or above the first carrier substrate; forming a plurality of second lands on second carrier substrates; forming second insulating films on the plurality of second lands formed on the second carrier substrates; forming second openings in each of the second insulating films, wherein the second openings have different opening areas and expose the surfaces of the second lands; varying the thicknesses of the second lands by etching the surfaces of the second lands through the second openings; mounting second semiconductor chips on or above the second carrier substrates; forming bumps on the second lands; and arranging the second carrier substrates on or above the first carrier substrate by bonding the bumps formed on the second lands to the first lands.

Therefore, in this method, the lands having different thicknesses are formed on the first carrier substrate and the second carrier substrates in a single step. Therefore, variations in the spaces between the first carrier substrate and the second carrier substrates are accommodated by both the first lands and the second lands without repeatedly forming the lands having different thicknesses. As a result, the second carrier substrates mounted on or above the first carrier substrate have uniform height without complicating the manufacturing process.

According to an aspect of the present invention, a method for manufacturing an electronic device has the steps of: forming a plurality of first lands that have different thicknesses from each other on a first carrier substrate; mounting a first electronic component on the first carrier substrate; forming a plurality of second lands that have different thicknesses from each other on second carrier substrates; mounting second electronic components on the second carrier substrates; forming bumps on the second lands; and arranging the second carrier substrates on or above the first carrier substrate by bonding the bumps formed on the second lands to the first lands.

Therefore, in this method, variations in the spaces between the first carrier substrate and the second carrier substrates are accommodated by both the first lands and the second lands. Thus, the second carrier substrates mounted on or above the first carrier substrate have uniform height without adjusting the sizes of bumps or the amount of supplementary solder.

### BRIEF DESCRIPTION OF THE DRAWINGS

FIG. 1 is a cross-sectional view illustrating a semiconductor device according to a first embodiment of the present invention.

FIGS. 2A-C are cross-sectional views illustrating a method for manufacturing the semiconductor device shown in FIG. 1.

FIG. 3 is a cross-sectional view illustrating a semiconductor device according to a second embodiment of the present invention.

FIGS. 4A-D are cross-sectional views illustrating a method for manufacturing a carrier substrate according to a third embodiment of the present invention.

FIG. 5 is a cross-sectional view illustrating a semiconductor device according to a fourth embodiment of the present invention.

FIG. 6 is a cross-sectional view illustrating a semiconductor device according to a fifth embodiment of the present invention.

### DETAILED DESCRIPTION

A semiconductor device, an electronic device, and methods for manufacturing thereof according to the present invention will be described below with reference to the drawings.

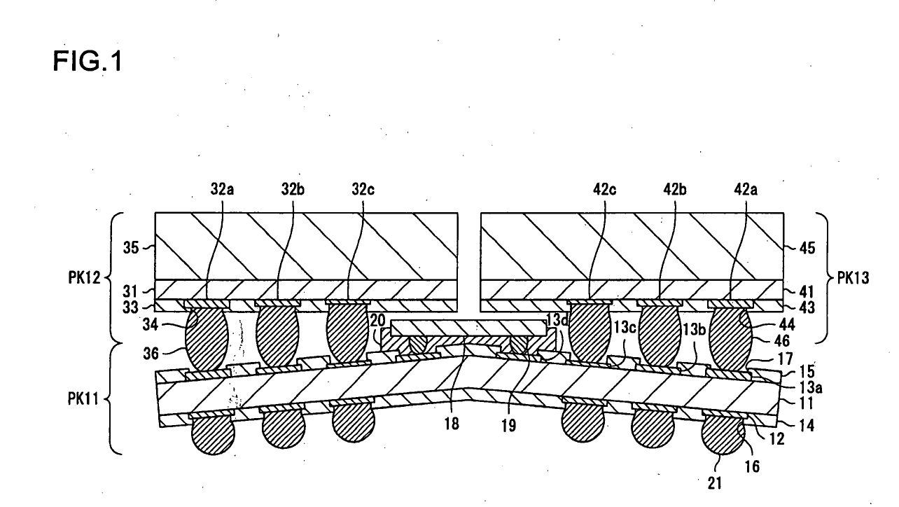

FIG. 1 shows a cross-sectional view illustrating a semiconductor device according to a first embodiment of the present invention. In this embodiment, lands 13a to 13c, 32a to 32c, and 42a to 42c of semiconductor packages PK11 to PK13 are bonded to bumps 36 and 46 and have different thicknesses.

Referring to FIG. 1, the semiconductor package PK11 has a carrier substrate 11, and a land 12 for arranging a bump 21 is disposed on the underside of the carrier substrate 11. On the underside of the carrier substrate 11 on which the land 12 is disposed, an insulating film 14, such as a solder resist, is formed. The insulating film 14 has an opening 16 that exposes the surface of the land 12.

The lands 13a to 13c for arranging the bumps 36 and 46 and a land 13d for arranging a bump 19 are disposed on the front side of the carrier substrate 11. On the front side of the carrier substrate 11 on which the lands 13a to 13d are disposed, an insulating film 15, such as a solder resist, is formed. The insulating film 15 has openings 17 that expose the surfaces of the lands 13a to 13d.

The thickness of each of the lands 13a to 13c formed on the front side of the carrier substrate 11 may gradually increase from the inner region to the outer region of the carrier substrate 11.

A semiconductor chip 18 is flip-chip mounted on or above the carrier substrate 11. The bump 19 is disposed on the semiconductor chip 18 for the flip-chip mounting and is bonded to the land 13d with an anisotropic conductive sheet 20 by anisotropic conductive film (ACF) bonding. The bump 21 for mounting the carrier substrate 11 on or above a motherboard is disposed on the land 12 formed on the underside of the carrier substrate 11.

The semiconductor packages PK12 and PK13 have carrier substrates 31 and 41, respectively. The lands 32a to 32c and 42a to 42c for arranging the bumps 36 and 46 are disposed on undersides of the carrier substrates 31 and 41, respectively. Insulating films 33 and 43, such as solder resists, are formed on the undersides, where the lands 32a to 32c and 42a to 42c are disposed, of the carrier substrates 31 and 41, respectively. The insulating films 33 and 43 have openings 34 and 44 for exposing the surfaces of the lands 32a to 32c and 42a to 42c, respectively. Semiconductor chips are mounted on or above the carrier substrates 31 and 41. The sides of the carrier substrates 31 and 41 which the semiconductor chips are mounted on or above are entirely sealed with sealing resin 35 and 45, respectively. The semiconductor chips that are connected by wire bonding may be mounted on or above the carrier substrates 31 and 41. The semiconductor chips may be flip-chip mounted. The semiconductor chips may have a composite structure.

The thickness of each of the lands 32a to 32c and 42a to 42c formed on the undersides of the carrier substrates 31 and 41 may gradually increase from the inner region to the outer region of the carrier substrates 31 or 41.

The bumps 36 and 46 are disposed on the lands 32a to 32c and 42a to 42c, which are disposed on the undersides of the carrier substrates 31 and 41, for mounting the carrier substrates 31 and 41 so as to hold an end of each of the carrier substrates 31 and 41 right above the semiconductor chip 18. The bumps 36 and 46 may be disposed away from the mounting region of the semiconductor chip 18. The bumps 36 and 46 may be, for example, disposed around the undersides of the carrier substrates 31 and 41, respectively.

The semiconductor package PK11 is warped downward because of the difference in the coefficient of linear expansion between the carrier substrate 11 and the semiconductor chip 18. The carrier substrates 31 and 41 may be mounted on or above the carrier substrate 11 by bonding the bumps 36 and 46 to the lands 13a to 13c formed on the carrier substrate 11 when the semiconductor package PK11 is warped downward.

The thickness of each of the lands 13a to 13c, 32a to 32c, and 42a to 42c of the semiconductor packages PK11 to PK13 varies, thereby accommodating variations in the spaces between the semiconductor package PK11 and the semiconductor packages PK12 and PK13 by the lands 13a to 13c, 32a to 32c, and 42a to 42c. Therefore, the semiconductor packages PK12 and PK13 are mounted on the semiconductor package PK11 without increasing variations in height of the semiconductor packages PK12 and PK13, even when the semiconductor package PK11 is warped.

The thickness of each of the lands 13a to 13c, 32a to 32c, and 42a to 42c of the semiconductor packages PK11 to PK13 varies, thereby accommodating variations in the spaces between the semiconductor package PK11 and the semiconductor packages PK12 and PK13 without changing the sizes of bumps 36 and 46, even when the semiconductor package PK11 is warped. Therefore, the semiconductor packages PK12 and PK13 mounted on the semiconductor package PK11 have uniform height without decreasing the mounting efficiency.

The carrier substrates 11, 31, and 41 may be, for example, a double-sided substrate, a substrate having a multi-level interconnection, a build-up substrate, a tape substrate, or a film substrate. The material of carrier substrates 11, 31, and 41 may be, for example, a polyimide resin, a glass epoxy resin, a bismaleimide-triazin (BT) resin, an aramid-epoxy composite, or ceramic. The bumps 19, 21, 36, and 46 may be, for example, a gold bump, a copper bump or nickel bump that is covered with a soldering agent, or a solder ball.

In the above-described embodiment, ACF bonding is used in a method for mounting the semiconductor chip 18 on or above the carrier substrate 11. Alternatively, other adhesive bonding, such as nonconductive film (NCF) bonding, or metallic bonding, such as solder bonding or alloy bonding, may be employed. The spaces between the carrier substrate 11 and the carrier substrates 31 and 41 may be filled with resin, if required.

In the above-described embodiment, the case where the carrier substrates 31 and 41, i.e. the upper substrates, are not warped and the carrier substrate 11, i.e. the lower substrate, is warped downward is discussed as an example. Similarly, the following cases are also applicable: the lower carrier substrate 11 is warped downward and the upper carrier substrates 31 and 41 are warped upward; the lower carrier substrate 11 is not warped and the upper carrier substrates 31 and 41 are warped upward; the carrier substrates 11, 31, and 41 are all warped downward and the carrier substrate 11 is more warped; and the carrier substrates 11, 31, and 41 are all warped upward and the carrier substrates 31 and 41 are more warped.

Additionally, the following cases are also applicable: the lower carrier substrate 11 is warped upward and the upper carrier substrates 31 and 41 are warped downward; the lower carrier substrate 11 is not warped and the upper carrier substrates 31 and 41 are warped downward; the upper carrier substrates 31 and 41 are not warped and the lower carrier substrate 11 is warped upward; the carrier substrates 11, 31, and 41 are all warped downward and the upper carrier substrates 31 and 41 are more warped; the carrier substrates 11, 31, and 41 are all warped upward and the lower carrier substrate 11 is more warped. In these cases, preferably, the thickness of each of the lands 13a to 13c, 32a to 32c, and 42a to 42c, all of which are formed on the surfaces of the carrier substrates 11, 31, and 41 may, for example, decrease from the inner region to the outer region of the carrier substrates 11, 31, or 41.

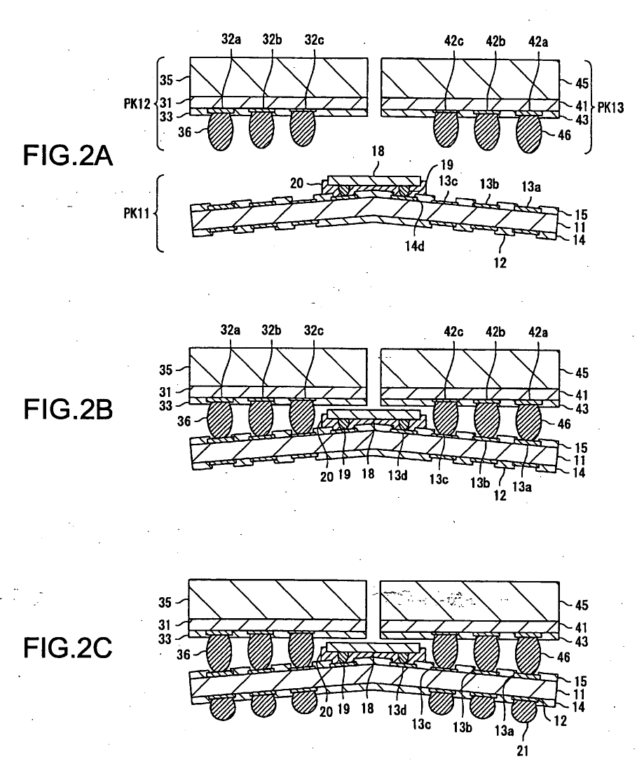

FIG. 2 is a cross-sectional view illustrating a method for manufacturing the semiconductor device shown in FIG. 1.

Referring to FIG. 2(a), the semiconductor package PK11 is warped downward. When the semiconductor packages PK12 and PK13 are arranged on the semiconductor package PK11, the bumps 36 and 46 are formed on the lands 32a to 32c and 42a to 42c of the carrier substrates 31 and 41, respectively. If solder balls are used as the bumps 36 and 46, for example, the diameters of the balls may be substantially the same.

Then, as shown in FIG. 2(b), the semiconductor packages PK12 and PK13 in which the bumps 36 and 46 are formed are each mounted on the semiconductor package PK11 and are subjected to solder reflow, thereby bonding the bumps 36 and 46 to the lands 32a to 32c and 42a to 42c.

The lands 32a to 32c and 42a to 42c have different thicknesses so that the mounting height of the carrier substrates 31 and 41 can be adjusted to compensate for the warping of the carrier substrate 11, even when the solder balls having substantially the same diameters are used as the bumps 36 and 46.

Then, as shown in FIG. 2(c), the bump 21 for mounting the carrier substrate 11 on or above the motherboard is formed on the land 12 disposed on the underside of the carrier substrate 11.

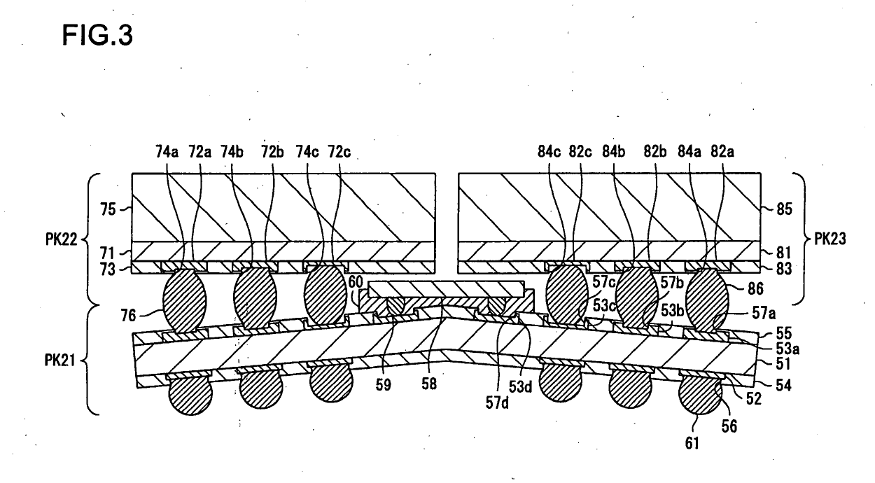

FIG. 3 is a cross-sectional view illustrating a semiconductor device according to a second embodiment of the present invention. In this embodiment, lands 53a to 53c, 72a to 72c, and 82a to 82c have different thicknesses in accordance with opening areas of openings 57a to 57c, 74a to 74c, and 84a to 84c of insulating films 55, 73, and 83, respectively. The insulating films 55, 73, and 83 are formed on the lands 53a to 53c, 72a to 72c, and 82a to 82c, respectively.

Referring to FIG. 3, a semiconductor package PK21 has a carrier substrate 51, and a land 52 for arranging a bump 61 is disposed on the underside of the carrier substrate 51. On the underside of the carrier substrate 51 on which the land 15 is disposed, an insulating film 54, such as a solder resist, is formed. The insulating film 54 has an opening 56 that exposes the surface of the land 52.

The lands 53a to 53c for arranging bumps 76 and 86 and a land 53d for arranging a bump 59 are disposed on the front side of the carrier substrate 51. On the front side of the carrier substrate 51 on which the lands 53a to 53d are disposed, the insulating film 55, such as a solder resist, is formed. The insulating film 55 has openings 57a to 57d that expose the surfaces of the lands 53a to 53d.

The thickness of each of the lands 53a to 53c formed on the front side of the carrier substrate 51 may gradually increase from the inner region to the outer region of the carrier substrate 51. The opening areas of the openings 57a to 57c may decrease as the thicknesses of the lands 53a to 53c increase, respectively.

A semiconductor chip 58 is flip-chip mounted on or above the carrier substrate 51. The bump 59 is disposed on the semiconductor chip 58 for the flip-chip mounting and is bonded to the surface of the land 53d with an anisotropic conductive sheet 60 by ACF bonding. A bump 61 for mounting the carrier substrate 51 on or above a motherboard is disposed on the land 52 formed on the underside of the carrier substrate 51.

The semiconductor packages PK22 and PK23 have carrier substrates 71 and 81, respectively. The lands 72a to 72c and 82a to 82c for arranging the bumps 76 and 86 are disposed on the undersides of the carrier substrates 71 and 81, respectively. The insulating films 73 and 83, such as solder resists, are formed on the undersides, where the lands 72a to 72c and 82a to 82c are disposed, of the carrier substrates 71 and 81, respectively. The insulating films 73 and 83 have the openings 74a to 74c and 84a to 84c for exposing the surfaces of the lands 72a to 72c and 82a to 82c, respectively. Semiconductor chips are mounted on or above the carrier substrates 71 and 81. The sides of the carrier substrates 71 and 81 which the semiconductor chips are mounted on or above are entirely sealed with sealing resin 75 and 85, respectively. The semiconductor chips connected by wire bonding may be mounted on or above the carrier substrates 71 and 81. The semiconductor chips may be flip-chip mounted. The semiconductor chips may have a composite structure.

The thickness of each of the lands 72a to 72c and 82a to 82c formed on the undersides of the carrier substrates 71 and 81 may gradually increase from the inner region to the outer region of the carrier substrates 71 or 81. The opening areas of the openings 74a to 74c and 84a to 84c may decrease as the thicknesses of the lands 72a to 72c and 82a to 82c increase, respectively.

The bumps 76 and 86 are disposed on the lands 72a to 72c and 82a to 82c, which are disposed on the undersides of the carrier substrates 71 and 81, for mounting the carrier substrates 71 and 81 so as to hold an end of each of the carrier substrates 71 and 81 right above the semiconductor chip 58. The bumps 76 and 86 may be disposed away from the mounting region of the semiconductor chip 58. The bumps 76 and 86 may be, for example, disposed around the undersides of the carrier substrates 71 and 81, respectively.

The bumps 76 and 86 are bonded to the lands 53a to 53c disposed on the carrier substrate 51 when, for example, the semiconductor package PK21 is warped downward so that the carrier substrates 71 and 81 can be mounted on or above the carrier substrate 51.

The lands 53a to 53c, 72a to 72c, and 82a to 82c of the semiconductor packages PK21 to PK23 have different thicknesses, thereby accommodating variations in the spaces between the semiconductor package PK21 and the semiconductor packages PK22 and PK23 by the lands 53a to 53c, 72a to 72c, and 82a to 82c. Therefore, the semiconductor packages PK22 and PK23 are mounted on the semiconductor package PK21 without increasing variations in height of the semiconductor packages PK22 and PK23, even when the semiconductor package PK21 is warped.

The opening area of each of the openings 57a to 57c, 74a to 74c, and 84a to 84c varies in accordance with the thickness of each of the lands 53a to 53c, 72a to 72c, and 82a to 82c so that the thickness of each of the lands 53a to 53c, 72a to 72c, and 82a to 82c can be varied by etching the surfaces of the lands 53a to 53c, 72a to 72c, and 82a to 82c. Therefore, the lands 53a to 53c, 72a to 72c, and 82a to 82c, which have different thicknesses, can be formed in a single step. Thus, it is not required to repeat forming the lands 53a to 53c, 72a to 72c, and 82a to 82c in accordance with the difference in thickness between the lands 53a to 53c, 72a to 72c, and 82a to 82c. As a result, the semiconductor packages PK22 and PK23 mounted on the semiconductor package PK21 have uniform height without complicating the manufacturing process.

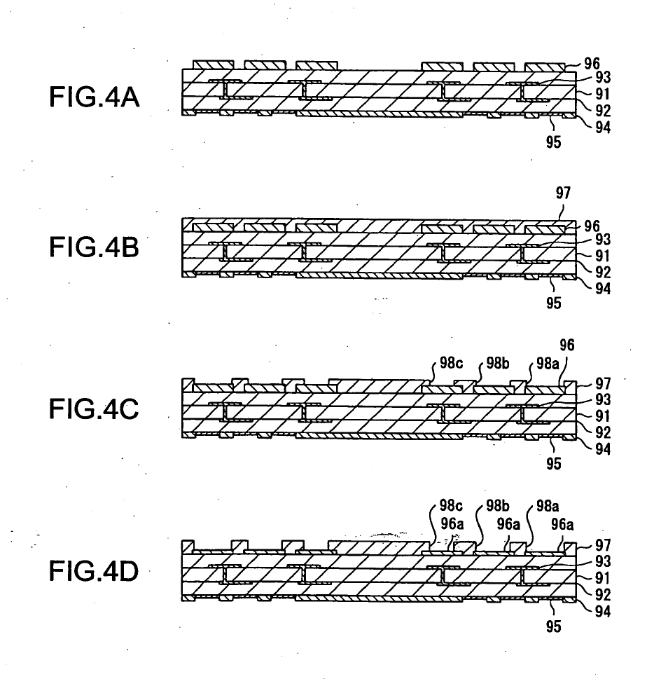

FIG. 4 is a cross-sectional view illustrating a method for manufacturing a carrier substrate according to a third embodiment of the present invention.

Referring to FIG. 4(a), a wiring pattern 93 is formed on wiring substrates 91. The wiring substrates 91 are stacked with an adhering layer 92 to form, for example, a four-layer substrate. Lands 95 having the same thicknesses are formed on the underside of the four-layer substrate. An insulating film 94, such as a solder resist, is formed so as to expose the surfaces of the lands 95. Lands 96 having the same thicknesses are formed by, for example, pattering a copper film formed on the front side of the four-layer substrate.

Then, as shown in FIG. 4(b), an insulating film 97, such as a photosolder, is formed on the front side of the four-layer substrate. Then, as shown in FIG. 4(c), openings 98a to 98c for exposing the surfaces of the lands 96 are formed by patterning the insulating film 97. The opening area of each of the openings 98a to 98c is adjusted to distortion or warping of a package mounted on the four-layer substrate. For example, the opening area of each of the openings 98a to 98c may increase from the inner region to the outer region of the four-layer substrate.

Subsequently, as shown in FIG. 4(d), the surfaces of the lands 96 are etched through the openings 98a to 98c. The etching rate can vary during etching of the surfaces of the lands 96 in accordance with the opening areas of the openings 98a to 98c. For example, the opening areas of the openings 98a to 98c may decrease so that the etching rate is reduced. Therefore, the surfaces of the lands 96 are etched through the openings 98a to 98c having different opening areas, thereby forming the lands 96a to 96c having different thicknesses in a single step. The lands 96a to 96c have different thicknesses without complicating the manufacturing process.

In the above-described embodiment, the four-layer substrate is illustrated as an example for explaining a method for manufacturing the carrier substrate. Alternatively, the carrier substrate may be a substrate other than the four-layer substrate.

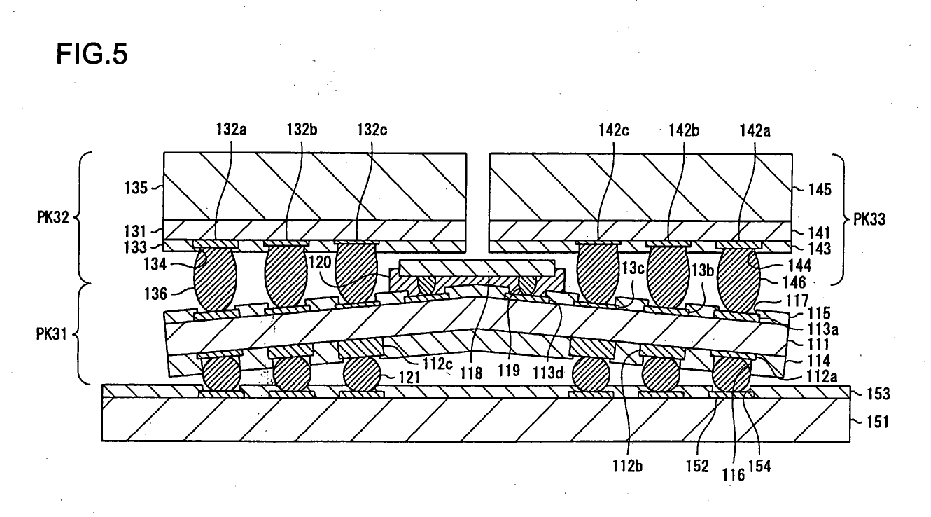

FIG. 5 is a cross-sectional view illustrating a semiconductor device according to a fourth embodiment of the present invention. In this embodiment, lands 113a to 113c, 132a to 132c, and 142a to 142c of semiconductor packages PK31 to PK33 are bonded to bumps 136 and 146 and have different thicknesses. Lands 112a to 112c on semiconductor package PK31 are bonded to bumps 121 and have different thicknesses.

Referring to FIG. 5, the semiconductor package PK31 has a carrier substrate 111, and the lands 112a to 112c for arranging the bumps 121 are disposed on the underside of the carrier substrate 111. On the underside of the carrier substrate 111 on which the lands 112a to 112c are disposed, an insulating film 114, such as a solder resist, is formed. The insulating film 114 has openings 116 that expose the surfaces of the lands 112a to 112c. The thickness of each of the lands 112a to 112c may, for example, gradually decrease from the inner region to the outer region of the carrier substrate 111.

The lands 113a to 113c for arranging the bumps 136 and 146 and a land 113d for arranging a bump 119 are disposed on the front side of the carrier substrate 111. On the front side of the carrier substrate 111 on which the lands 113a to 113d are disposed, an insulating film 115, such as a solder resist, is formed. The insulating film 115 has openings 117 that expose the surfaces of the lands 113a to 113d.

The thickness of each of the lands 113a to 113c formed on the front side of the carrier substrate 111 may, for example, gradually increase from the inner region to the outer region of the carrier substrate 111.

A semiconductor chip 118 is flip-chip mounted on or above the carrier substrate 111. The bump 119 is disposed on the semiconductor chip 118 for the flip-chip mounting and is bonded to the land 113d with an anisotropic conductive sheet 120 by ACF bonding. The bumps 121 for mounting the carrier substrate 111 on or above a motherboard 151 are disposed on the lands 112a to 112c formed on the underside of the carrier substrate 111.

The semiconductor packages PK32 and PK33 have carrier substrates 131 and 141, respectively. The lands 132a to 132c and 142a to 142c for arranging the bumps 136 and 146 are disposed on undersides of the carrier substrates 131 and 141, respectively. Insulating films 133 and 143, such as solder resists, are formed on the undersides, where the lands 132a to 132c and 142a to 142c are disposed, of the carrier substrates 131 and 141, respectively. The insulating films 133 and 143 have openings 134 and 144 for exposing the surfaces of the lands 132a to 132c and 142a to 142c, respectively. Semiconductor chips are mounted on or above the carrier substrates 131 and 141. The sides of the carrier substrates 131 and 141 which the semiconductor chips are mounted on or above are entirely sealed with sealing resin 135 and 145, respectively. The semiconductor chips that are connected by wire bonding may be mounted on or above the carrier substrates 131 and 141. The semiconductor chips may be flip-chip mounted. The semiconductor chips may have a composite structure.

The thickness of each of the lands 132a to 132c, 142a to 142c formed on the undersides of the carrier substrates 131 or 141 may gradually increase from the inner region to the outer region of the carrier substrates 131 or 141.

The bumps 136 and 146 are disposed on the lands 132a to 132c and 142a to 142c, which are disposed on the undersides of the carrier substrates 131 and 141, for mounting the carrier substrates 131 and 141 so as to hold an end of each of the carrier substrates 131 and 141 right above the semiconductor chip 118. The bumps 136 and 146 may be disposed away from the mounting region of the semiconductor chip 118. The bumps 136 and 146 may be, for example, disposed around the undersides of the carrier substrates 131 and 141, respectively.

Lands 152 for bonding the bumps 121 are formed on the motherboard 151. An insulating film 153, such as a solder resist, is formed on the motherboard 151 and has openings 154 for exposing the surfaces of the lands 152.

The bumps 136 and 146 are bonded to the lands 113a to 113c disposed on the carrier substrate 111 when, for example, the semiconductor package PK31 is warped downward so that the carrier substrates 131 and 141 can be mounted on or above the carrier substrate 111. The bumps 121 are bonded to the lands 152 disposed on the motherboard 151 so that the carrier substrate 111 which the carrier substrates 131 and 141 are arranged on or above can be mounted on or above the motherboard 151.

The lands 113a to 113c, 132a to 132c, and 142a to 142c of the semiconductor packages PK31 to PK33 have different thicknesses, thereby accommodating variations in the spaces between the semiconductor package PK31 and the semiconductor packages PK32 and PK33 by the lands 113a to 113c, 132a to 132c, and 142a to 142c. Therefore, the semiconductor packages PK32 and PK33 are mounted on the semiconductor package PK31 without increasing variations in height of the semiconductor packages PK32 and PK33, even when the semiconductor package PK31 is warped.

The lands 112a to 112c of the semiconductor package PK31 have different thicknesses, thereby accommodating variations in the spaces between the semiconductor package PK31 and the motherboard 151 by the lands 112a to 112c. Therefore, the semiconductor packages PK31 is mounted stably on or above the motherboard 151 without changing the height of the bumps 121, even when the semiconductor package PK31 is warped.

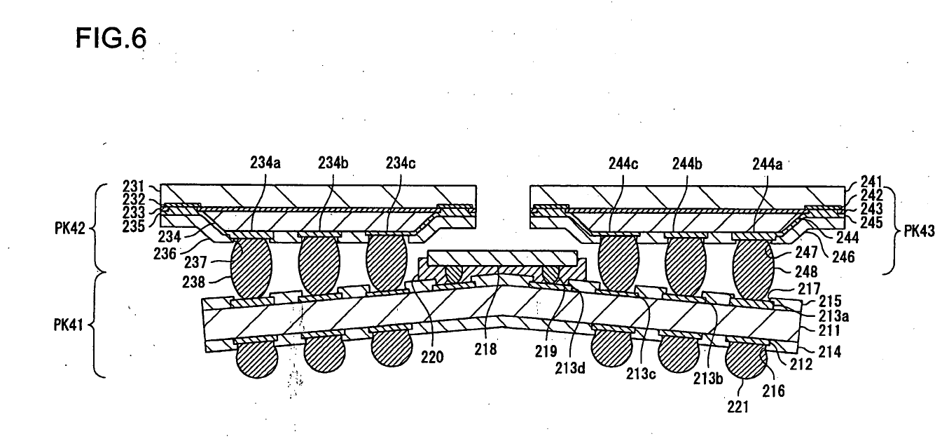

FIG. 6 is a cross-sectional view illustrating a semiconductor device according to a fifth embodiment of the present invention. In this embodiment, lands 213a to 213c, 234a to 234c, and 244a to 244c of semiconductor packages PK41 to PK43 are bonded to bumps 238 and 248 and have different thicknesses, and a wafer level chip size package (W-CSP) is used for the semiconductor packages PK42 and PK43.

Referring to FIG. 6, the semiconductor package PK41 has a carrier substrate 211, and a land 212 for arranging a bump 221 is disposed on the underside of the carrier substrate 211. On the underside of the carrier substrate 211 on which the land 212 is disposed, an insulating film 214, such as a solder resist, is formed. The insulating film 214 has an opening 216 that exposes the surface of the land 212.

The lands 213a to 213c for arranging the bumps 238 and 248 and a land 213d for arranging a bump 219 are disposed on the front side of the carrier substrate 211. On the front side of the carrier substrate 211 on which the lands 213a to 213d are disposed, an insulating film 215, such as a solder resist, is formed. The insulating film 215 has openings 217 that expose the surfaces of the lands 213a to 213d.

The thickness of each of the lands 213a to 213c formed on the front side of the carrier substrate 211 may, for example, gradually increase from the inner region to the outer region of the carrier substrate 211.

A semiconductor chip 218 is flip-chip mounted on or above the carrier substrate 211. The bump 219 is disposed on the semiconductor chip 218 for the flip-chip mounting and is bonded to the land 213d with an anisotropic conductive sheet 220 by ACF bonding. The bump 221 for mounting the carrier substrate 211 on or above a motherboard is disposed on the land 216 formed on the underside of the carrier substrate 211.

The semiconductor packages PK42 and PK43 have semiconductor chips 231 and 241, respectively. Electrode pads 232 and 242 are disposed on the semiconductor chips 231 and 241, respectively. Insulating films 233 and 243 are arranged so that the surfaces of the electrode pads 232 and 242 are exposed. Stress relief layers 234 and 244 are formed on the semiconductor chips 231 and 241, respectively, so that the electrode pads 232 and 242 are exposed. Redistribution wiring lines 235 and 245 that extend along the stress relief layers 234 and 244 are formed on the electrode pads 232 and 242, respectively. Lands 234a to 234c and 244a to 244c for arranging the bumps 238 and 248 are disposed on the stress relief layers 234 and 244, respectively. Solder resist film 236 is formed on the redistribution wiring line 235 and the lands 234a to 234c. Solder resist film 246 is formed on the redistribution wiring line 245 and the lands 244a to 244c. The solder resist films 236 and 246 have openings 237 and 247 so as to expose the lands 234a to 234c and 244a to 244c on the stress relief layers 234 and 244.

The thickness of each of the lands 234a to 234c and 244a to 244c formed on the stress relief layers 234 and 244 may, for example, gradually increase from the inner region to the outer region of the semiconductor chips 231 or 241.

The bumps 238 and 248 are disposed on the lands 234a to 234c and 244a to 244c, which are exposed through the openings 237 and 247, for face-down mounting the semiconductor chips 231 and 241, respectively, so as to hold an end of each of the semiconductor chips 231 and 241 right above the semiconductor chip 218. The bumps 238 and 248 may be disposed away from the mounting region of the semiconductor chip 218. The bumps 238 and 248 may be, for example, disposed around the semiconductor chips 231 and 241, respectively.

The bumps 238 and 248 are bonded to the lands 213a to 213c disposed on the carrier substrate 211 when, for example, the semiconductor package PK41 is warped downward so that the semiconductor chips 231 and 241 can be mounted on or above the carrier substrate 211.

Therefore, the W-CSPs are arranged on or above the carrier substrate 211 which the semiconductor chip 218 is flip-chip mounted on or above. Thus, the semiconductor chips 231 and 241 are three-dimensionally mounted on or above the semiconductor chip 218 without requiring a carrier substrate between the semiconductor chips 218, 231, and 241, even when the semiconductor chips 218, 231, and 241 are different in size or type. Additionally, variations in the spaces between the semiconductor package PK41 and the semiconductor packages PK42 and PK43 are accommodated by the lands 213a to 213c, 234a to 234c, and 244a to 244c.

As a result, the semiconductor packages PK42 and PK43 mounted on the semiconductor package PK41 have uniform height without increasing the mounting height of the semiconductor chips 231 and 241, even when the semiconductor package PK41 is warped.

The above-described semiconductor device and electronic device are applicable to electronic apparatuses, such as liquid crystal displays, cellular phones, personal digital assistants, video cameras, digital cameras, or mini disc (MD) players, allowing miniaturization and improvement in reliability of the electronic apparatuses.

Although the above-described embodiments are illustrated with a method for mounting semiconductor chips or semiconductor packages, the present invention is not restricted to such a method. In the present invention, ceramic devices, such as surface-acoustic-wave (SAW) devices, optical devices, such as optical modulators or optical switches, and sensors, such as magnetic sensors or biosensors, may be mounted.

What is claimed is:

1. A semiconductor device comprising:
a carrier substrate having a plurality of lands that have different thicknesses from each other; and
a semiconductor chip mounted to the carrier substrate.

2. The semiconductor device according to claim 1, wherein the thickness of each of the lands gradually varies from the inner region to the outer region of the carrier substrate.

3. A semiconductor device comprising:
a first semiconductor package having a plurality of first lands that have different thicknesses from each other; and
second semiconductor packages, each having a plurality of second lands that have different thicknesses from each other, the second lands being arranged opposite the first lands.

4. The semiconductor device according to claim 3, wherein the thickness of each of the first lands and the second lands gradually increases as a space between the first semiconductor package and the second semiconductor packages increases.

5. The semiconductor device according to claim 3, further including bumps bonded to the lands.

6. The semiconductor device according to claim 5, wherein the bumps have substantially the same volume.

7. The semiconductor device according to claim 3, further including:
insulating films formed on the lands; and
openings that are formed in the insulating films and have different opening areas corresponding to the thicknesses of the lands.

8. The semiconductor device according to claim 7, wherein the opening areas of the openings decrease as the thicknesses of the lands increase.

9. The semiconductor device according to claim 3, wherein:
the first semiconductor package includes:
a first carrier substrate having the first lands; and
a first semiconductor chip that are flip-chip mounted to the first carrier substrate, and
the second semiconductor packages includes:
second carrier substrates having the second lands;
second semiconductor chips mounted to the second carrier substrates;
bumps for bonding the first lands and the second lands to hold an end of each of the second carrier substrates directly above the first semiconductor chip; and
seals for sealing the second semiconductor chips.

10. The semiconductor device according to claim 9, wherein the first semiconductor package further comprises a ball grid array package in which the first semiconductor chip is flip-chip mounted to the first carrier substrate, and each of the second semiconductor packages further comprises at least one of a ball grid array package and a chip-size package in which each of the second semiconductor chips mounted to each of the second carrier substrates is sealed by molding.

11. An electronic device comprising:
a first carrier substrate having a plurality of first lands that have different thicknesses from each other;
a first electronic component that is flip-chip mounted to the first carrier substrate;
second carrier substrates, each having a plurality of second lands that have different thicknesses from each other, the second lands being arranged opposite the first lands;
second electronic components mounted to the second carrier substrates; and
seals for sealing the second electronic components.

12. An electronic apparatus comprising:
a first semiconductor package having a plurality of first lands that have different thicknesses from each other;
second semiconductor packages, each having a plurality of second lands that have different thicknesses from each other, the second lands being arranged opposite the first lands; and
a motherboard having the second semiconductor packages.

13. A method for manufacturing a carrier substrate comprising the steps of:
forming a plurality of lands on a first carrier substrate;
forming an insulating film on the plurality of lands formed on the first carrier substrate;
forming openings in the insulating film, wherein the openings have different opening areas and expose the surfaces of the lands; and
varying the thicknesses of the lands by etching the surfaces of the lands through the openings.

14. A method for manufacturing a semiconductor device comprising the steps of:
forming a plurality of first lands that have different thicknesses from each other on a first carrier substrate;
mounting a first semiconductor chip to the first carrier substrate;
forming a plurality of second lands that have different thicknesses from each other on second carrier substrates;
mounting second semiconductor chips to the second carrier substrates;
forming bumps on the second lands; and
arranging the second carrier substrates relative to the first carrier substrate by bonding the bumps formed on the second lands to the first lands.

15. A method for manufacturing a semiconductor device comprising the steps of:
forming a plurality of first lands on a first carrier substrate;
forming a first insulating film on the plurality of first lands formed on the first carrier substrate;
forming first openings in the first insulating film, wherein the first openings have different opening areas and expose the surfaces of the first lands;
varying the thicknesses of the first lands by etching the surfaces of the first lands through the first openings;
mounting a first semiconductor chip to the first carrier substrate;
forming a plurality of second lands on second carrier substrates;
forming second insulating films on the plurality of second lands formed on the second carrier substrates;
forming second openings in each of the second insulating films, wherein the second openings have different opening areas and expose the surfaces of the second lands;
varying the thicknesses of the second lands by etching the surfaces of the second lands through the second openings;
mounting second semiconductor chips to the second carrier substrates;
forming bumps on the second lands; and
arranging the second carrier substrates relative to the first carrier substrate by bonding the bumps formed on the second lands to the first lands.

16. A method for manufacturing an electronic device comprising the steps of:
forming a plurality of first lands that have different thicknesses from each other on a first carrier substrate;
mounting a first electronic component on the first carrier substrate;
forming a plurality of second lands that have different thicknesses from each other on second carrier substrates;
mounting second electronic components on the second carrier substrates;
forming bumps on the second lands; and
arranging the second carrier substrates relative to the first carrier substrate by bonding the bumps formed on the second lands to the first lands.
